(19) United States
(12) Patent Application Publication
(10) Pub. No.: US 2025/0212436 A1
(43) Pub. Date: Jun. 26, 2025

(54) SEMICONDUCTOR DEVICE

(71) Applicant: FUJI ELECTRIC CO., LTD., Kanagawa (JP)

(72) Inventors: Toru MURAMATSU, Matsumoto-city (JP); Tatsuya NAITO, Matsumoto-city (JP)

(21) Appl. No.: 18/923,547

(22) Filed: Oct. 22, 2024

(30) Foreign Application Priority Data
Dec. 21, 2023 (JP) 2023-216298

(51) Int. Cl. H01L 29/739; H01L 29/08; H01L 29/10; H01L 29/861

(52) U.S. Cl. CPC H10D 12/481; H10D 8/00; H10D 62/133; H10D 62/393

(57) ABSTRACT

Provided is a semiconductor device with a transistor portion and a diode portion, including a drift region of a first conductivity type and a front surface side electrode provided above a semiconductor substrate. The transistor portion may have a base region of a second conductivity type provided above the drift region; a trench contact portion provided on a front surface of the semiconductor substrate; and a first plug region of a second conductivity type with a higher doping concentration than the base region, under the trench contact portion. The diode portion may have an anode region of a second conductivity type provided above the drift region; and a second plug region of a second conductivity type with a higher doping concentration than the anode region. The second plug region may contact the front surface side electrode in a position shallower than the first plug region.

The contents of the following patent application(s) are incorporated herein by reference:
NO. 2023-216298 filed in JP on Dec. 21, 2023

### BACKGROUND

### 1. Technical Field

The present invention relates to a semiconductor device.

### 2. Related Art

A semiconductor device with “a trench contact portion 60 provided in each of a mesa portion 71 and a mesa portion 81” and “a plug region 19 provide in a bottom portion of a trench contact portion 60 in each of the mesa portion 71 and the mesa portion 81” is described in Patent Document 1, a semiconductor device with “a trench contact portion and a plug region discretely provided in a diode portion” is described in Patent Document 2, and a semiconductor device with “an anode contact layer 28 partially formed in a surface layer portion of an anode layer 30” is described in Patent Document 3, respectively.

### PRIOR ART DOCUMENT

### Patent Document

Patent Document 1: Japanese Patent Application Publication No. 2023-135082.
Patent Document 2: Japanese Patent Application Publication No. 2023-19322.
Patent Document 3: International Publication No. 2014/125584.

### BRIEF DESCRIPTION OF THE DRAWINGS

FIG. 1A shows one example of an upper surface of a semiconductor device 100.

FIG. 1B shows one example of a cross section a-a′ of the semiconductor device 100.

FIG. 1C shows one example of a cross section b-b′ of the semiconductor device 100.

FIG. 1D shows one example of a cross section c-c′ of the semiconductor device 100.

FIG. 1E shows one example of a cross section d-d′ of the semiconductor device 100.

FIG. 2 shows a variant example of the cross section a-a′ of the semiconductor device 100.

FIG. 3 shows a variant example of an upper surface of the semiconductor device 100.

FIG. 4 shows a Vf-If characteristic of the semiconductor device 100.

FIG. 5 shows a Vf-Err characteristic of the semiconductor device 100.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are imperative to the solutions of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z-axis direction and a −Z-axis direction are directions opposite to each other. When the Z-axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

In the present specification, a description of a P+ type or an N+ type means a higher doping concentration than that of the P type or the N type, and a description of a P-type or an N-type means a lower doping concentration than that of the P-type or the N-type.

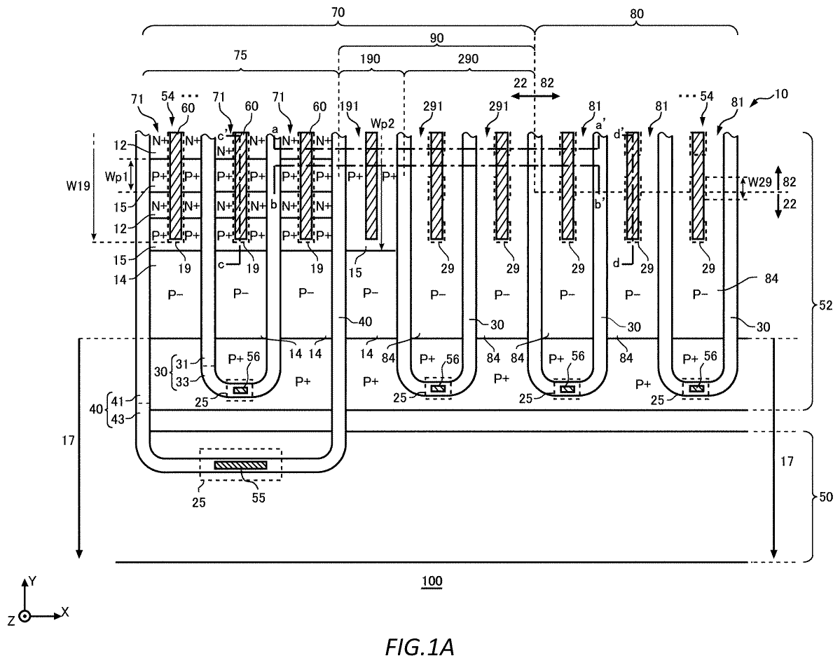

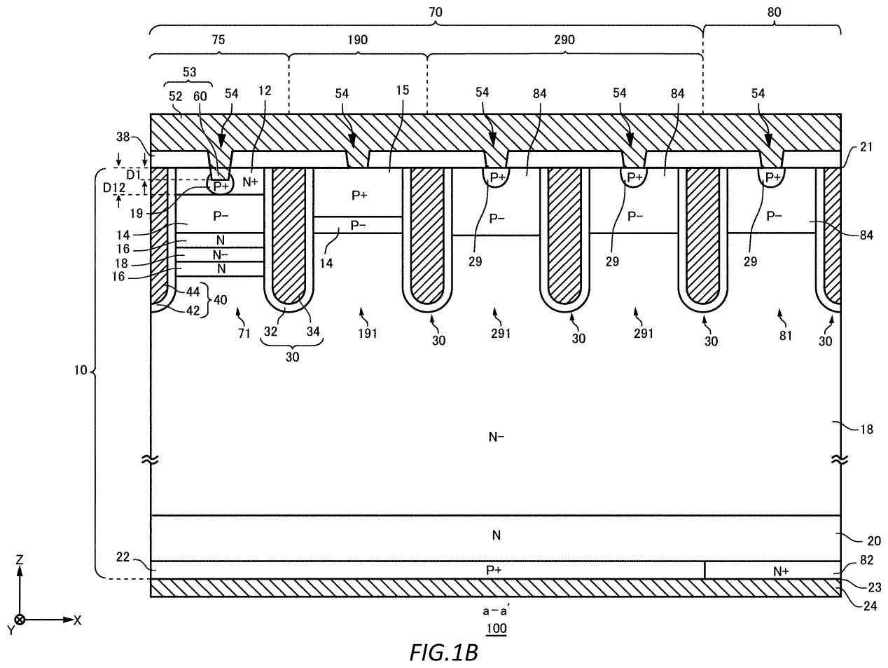

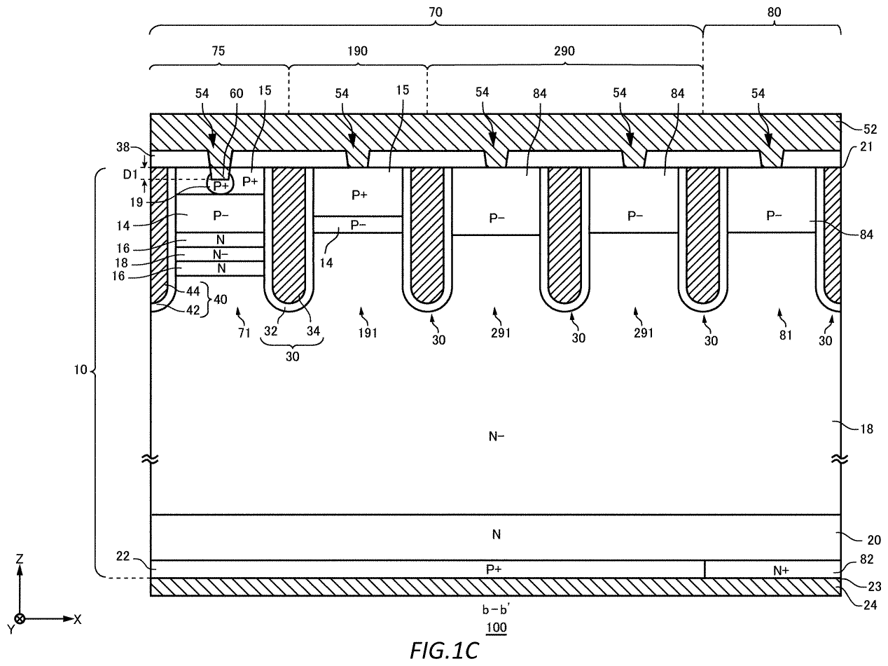

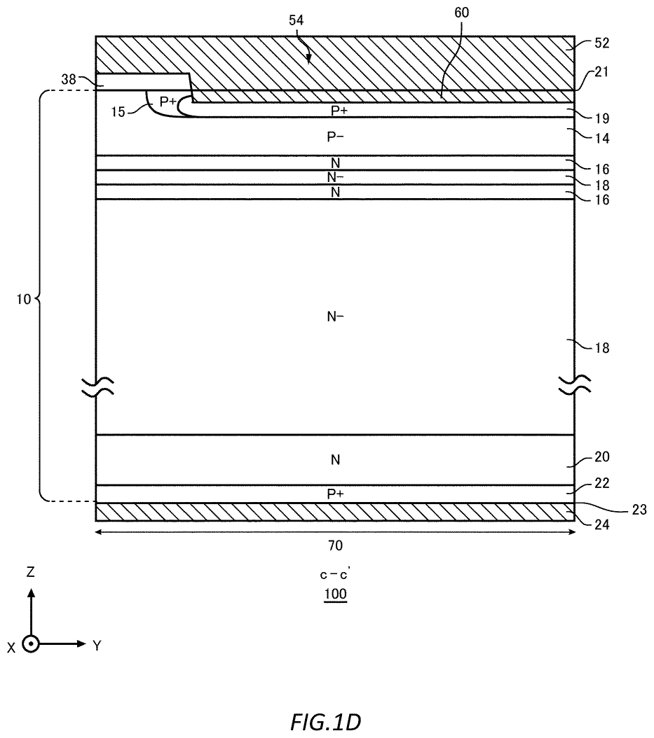

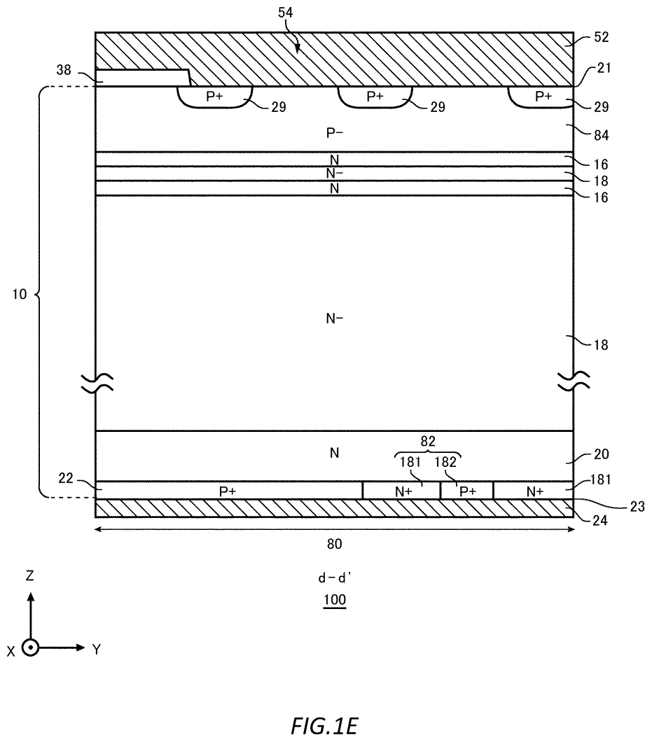

FIG. 1A shows an example of an upper surface of a semiconductor device 100. The semiconductor device 100 of the present example includes the transistor portion 70 and a diode portion 80. For example, the semiconductor device 100 is a reverse conducting IGBT (RC-IGBT: Reverse Conducting IGBT).

The transistor portion 70 is a region obtained by projecting a collector region 22 provided on a rear surface 23 side of a semiconductor substrate 10 onto an upper surface of the semiconductor substrate 10. The rear surface 23 is described below. The transistor portion 70 includes a transistor such as an IGBT. In the present example, the transistor portion 70 is an IGBT. It is to be noted that the transistor portion 70 may be other transistors such as a MOSFET.

The transistor portion 70 in the present example includes a main region 75 with emitter regions 12, and a boundary region 90 provided closer than the main region 75 to the diode portion 80. The main region 75 is a region acting as a transistor during operations of the semiconductor device 100. In mesa portions 71 in the main region 75, the emitter regions 12 and contact regions 15 are provided alternately in an extending direction on the front surface 21 of the semiconductor substrate 10. The front surface 21 will be described below.

The diode portion 80 is a region obtained by projecting the cathode region 82 provided on the rear surface 23 side of the semiconductor substrate 10 onto the upper surface of the semiconductor substrate 10. The diode portion 80 includes a diode such as a free wheel diode (FWD) provided so as to be in direct contact with the transistor portion 70 on the front surface of the semiconductor substrate 10. The rear surface of the semiconductor substrate 10 may be provided with a collector region of a P+ type in a region other than the cathode region.

The boundary region 90 does not have the emitter region 12. That is, the boundary region 90 is a region that does not act as a transistor during operations of the semiconductor device 100. By providing the boundary region 90 that does not act as a transistor between the main region 75 and the diode portion 80, hole implantation can be suppressed during reverse recovery operation of the semiconductor device 100. The boundary region 90 has a first boundary portion 190 and a second boundary portion 290.

The first boundary portion 190 includes a contact region 15 on the front surface 21 of the semiconductor substrate 10. In the first boundary portion 190, the contact region 15 is provided to extend from a base region 14 of an end portion on a negative side in a trench extending direction (the Y-axis direction in the present example) to the base region 14 of an end portion on a positive side in the trench extending direction. The first boundary portion 190 may be provided in a mesa portion closest to the main region 75 among one or more mesa portions with the boundary region 90. The first boundary portion 190 may be provided across the plurality of mesa portions. The first boundary portion 190 in the present example has one mesa portion 191.

The second boundary portion 290 is provided closer than the first boundary portion 190 to the diode portion 80, including anode regions 84 on the front surface 21 of the semiconductor substrate 10. The second boundary portion 290 may be provided across the plurality of mesa portions. The second boundary portion 290 in the present example has two mesa portions 291, but may also have 3 or more mesa portions 291.

The present figure illustrates a region around an active portion of the semiconductor device 100 and other regions are omitted. For example, an edge termination structure portion may be provided in a region on a negative side of the Y-axis direction in the semiconductor device 100 in the present example. The edge termination structure portion reduces electric field strength on an upper surface side of the semiconductor substrate 10. The edge termination structure portion includes, for example, a guard ring, a field plate, or a RESURF structure, or combinations thereof. Note that although the present example describes the edge on the negative side in the Y-axis direction for convenience, the same applies to other edges of the semiconductor device 100.

The semiconductor substrate 10 is a substrate that is formed of a semiconductor material. The semiconductor substrate 10 may be a silicon substrate or may be a silicon carbide substrate. The semiconductor substrate 10 in the present example is the silicon substrate.

The semiconductor device 100 in the present example includes emitter regions 12, base regions 14, contact regions 15, a well region 17, dummy trench portions 30, a gate trench portion 40 and anode regions 84 on the front surface 21 of the semiconductor substrate 10. The semiconductor device 100 in the present example includes first plug regions 19 and second plug regions 29 inside the semiconductor substrate 10. In addition, the semiconductor device 100 in the present example includes an emitter electrode 52 and a gate metal layer 50 which are provided above the front surface 21 of the semiconductor substrate 10.

The emitter region 12 is provided above the base region 14, and is a region of a first conductivity type with a higher doping concentration than the drift region 18 described below. The emitter region 12 is, for example, of an N+ type. Examples of a dopant of the emitter region 12 include arsenic (As). The emitter region 12 is provided in contact with the gate trench portion 40 at the front surface 21 in the mesa portion 71. The emitter region 12 may be provided to extend in the trench array direction (the X-axis direction in the present example) from one to another of two trench portions sandwiching the mesa portion 71.

In addition, the emitter region 12 may be or may not be in contact with the dummy trench portion 30. The emitter region 12 in the present example is in contact with the dummy trench portion 30.

The base region 14 is a region of the second conductivity type provided above the drift region 18. The base region 14 is of the P-type as an example. The doping concentration of the base region 14 may be 1E16 cm⁻³ or more, or may be 5E18 cm⁻³ or less. The base regions 14 may be provided at both end portions of the mesa portion 71 in the Y-axis direction in the front surface 21 of the semiconductor substrate 10. Note that FIG. 1A illustrates only one end portion in the Y-axis direction of the base region 14.

The contact region 15 is a region of a second conductivity type, which is provided above the base region 14 and has a higher doping concentration than the base region 14. The contact region 15 is, for example, of P+ type. The doping concentration of the contact region 15 may be 1E21 cm⁻³ or more, or may be 1E22 cm⁻³ or less.

The contact region 15 in the present example is provided on the front surface 21 of the mesa portion 71 and the mesa portion 191. That is, the contact region 15 of the present example is provided in the main region 75 and the first boundary portion 190. The contact region 15 may be provided in the trench array direction (the X-axis direction in the present example) from one to another of two trench portions sandwiching the mesa portion 71 and the mesa portion 191.

A width Wp2 of the contact region 15 provided in the first boundary portion 190 in the trench extending direction is greater than a width Wp1 of the contact region 15 provided in the main region 75 in the trench extending direction. The contact region 15 is provided alternately with the emitter region 12 in the trench extending direction in the mesa portion 71 of the main region 75. The contact region 15 is provided to extend in the trench extending direction in the mesa portion 191 of the first boundary portion 190.

The contact region 15 may or may not be in contact with the gate trench portion 40 of the dummy trench portion 30. The contact region 15 in the present example is in contact with the dummy trench portion 30 and the gate trench portion 40.

The well region 17 is a region of the second conductivity type provided above the drift region 18. The well region 17 is an example of the well region provided in a peripheral side of the active portion. The well region 17 is of the P+ type as an example. The well region 17 is formed in a predetermined range from an end portion of the active portion on a side where the gate metal layer 50 is provided. A diffusion depth of the well region 17 may be deeper than depths of the gate trench portion 40 and the dummy trench portion 30. Partial regions of the gate trench portion 40 and the dummy trench portion 30 in the gate metal layer 50 side are formed in the well region 17. The bottoms at the end of the extending direction of the gate trench portion 40 and the dummy trench portion 30 may be covered by the well region 17.

The anode region 84 is a region of the second conductivity type which is provided above the drift region 18. The anode region 84 is of the P-type as an example. The doping concentration of the anode region 84 may be lower than the doping concentration of the base region 14, or may be the same as the doping concentration of the base region 14. In one example, the doping concentration of the anode regions 84 is from 1E16 cm⁻³ to 1E18 cm⁻³ inclusive. By having the doping concentration of the anode region 84 lower than the doping concentration of the base region 14, a reverse recovery loss Err of the semiconductor device 100 can be reduced.

The first plug region 19 is a region of the second conductivity type with a higher doping concentration than the base region 14 provided below the trench contact portion 60 in the transistor portion 70. The first plug region 19 is, for example, of a P+ type. The doping concentration of the first plug region 19 may be the same as the doping concentration of the contact region 15, or may be higher than the doping concentration of the contact region 15. The doping concentration of the first plug region 19 in the present example is the same as the doping concentration of the contact region 15. In one example, the doping concentration of the first plug region 19 is from 1E21 cm⁻³ to 1E22 cm⁻³.

The second plug region 29 is a region of the second conductivity type with a higher doping concentration than the anode region 84. The second plug region 29 is, for example, of the P+ type. The doping concentration of the second plug region 29 may be the same as or may be different from the doping concentration of the first plug region 19. The doping concentration of the second plug region 29 in the present example is the same as the doping concentration of the first plug region 19.

In the diode portion 80, the second plug region 29 is provided alternately with the anode region 84 in the trench extending direction of the plurality of trench portions. That is, the second plug region 29 is provided selectively in the trench extending direction (the Y-axis direction in the present example).

In the trench extending direction, a width W19 of the first plug region 19 provided in the transistor portion 70 is greater than a width W29 of the second plug region 29 provided in the diode portion 80. The first plug region 19 may be provided to cover the overall below contact holes 54 in a top view. That is, the first plug region 19 may be provided continuously in the extending direction (the Y-axis direction in the present example) of the contact hole 54. This can facilitate extraction of holes through the first plug region 19 and suppress latch-up of the semiconductor device 100. It is to be noted that when simply referred to as a top view in the present specification, it means that the upper surface side of the semiconductor substrate 10 is viewed from above.

The second plug region 29 may be provided in the second boundary portion 290. That is, the second boundary portion 290 may include the second plug region 29. In the trench extending direction, the width of the second plug region 29 provided in the second boundary portion 290 may be less than the width of the first plug region 19 provided in the mesa portion 71. This can suppress the hole implantation during the reverse recovery operation of the semiconductor device 100.

The first plug region 19 and the second plug region 29 may be simultaneously formed by the same ion implantation process. As one example, a manufacturing method of the semiconductor device 100 includes forming the contact holes 54 in an interlayer insulating film 38 of the transistor portion 70 and the diode portion 80, etching the semiconductor substrate 10 exposed via the apertures of the contact hole 54 in the transistor portion 70, and implanting ion for forming the first plug region 19 and the second plug region 29. The interlayer insulating film 38 is to be described below. After the contact holes 54 are firstly formed in the transistor portion 70 and the semiconductor substrate 10 is etched, the step of forming the contact holes 54 in the diode portion 80 and ion implantation may be performed.

The emitter electrode 52 is provided above the gate trench portion 40, the dummy trench portion 30, the emitter region 12, the base region 14, the contact region 15, the well region 17, the connecting portion 25 and the anode region 84. The gate metal layer 50 is provided above the well region 17 and the connecting portion 25.

The emitter electrode 52 and the gate metal layer 50 are formed of a material including metal. At least a partial region of the emitter electrode 52 may be formed of metal such as aluminum (Al) or a metal alloy such as an aluminum-silicon alloy (AlSi) and an aluminum-silicon-copper alloy (AlSiCu). At least a partial region of the gate metal layer 50 may be formed of metal such as aluminum (Al) or a metal alloy such as an aluminum-silicon alloy (AlSi) and an aluminum-silicon-copper alloy (AlSiCu). The emitter electrode 52 and the gate metal layer 50 may include a barrier metal layer formed of titanium, a titanium compound, or the like under the region formed of aluminum and the like. The emitter electrode 52 and the gate metal layer 50 are provided separately from each other.

The emitter electrode 52 and the gate metal layer 50 are provided above the semiconductor substrate 10 to sandwich an interlayer insulating film 38. The interlayer insulating film 38 is omitted in FIG. 1A. A contact hole 54, a contact hole 55, and a contact hole 56 are provided through the interlayer insulating film 38.

The contact hole 54 is formed above each region of the emitter region 12, the contact region 15 and the anode region 84 in the transistor portion 70 and the diode portion 80. The contact hole 54 is not provided above the well regions 17 provided at both ends in the Y-axis direction. In this manner, one or more contact holes 54 are formed in the interlayer insulating film. One or more contact holes 54 may be provided to extend in the trench extending direction of the plurality of trench portions.

The emitter electrode 52 is electrically connected to the semiconductor substrate 10 via the contact hole 54. The trench contact portion 60 provided on the front surface 21 of the semiconductor substrate 10 may be formed below the contact hole 54.

A trench contact portion 60 electrically connects the emitter electrode 52 and the semiconductor substrate 10. The trench contact portion 60 is provided continuously from the contact hole 54. The trench contact portion 60 in the present example is provided in the mesa portion 71, and is not provided in the mesa portion 81, the mesa portion 191 and the mesa portion 291. That is, the trench contact portion 60 is not provided in the diode portion 80 or the boundary region 90.

The trench contact portion 60 contains a conductive material filled in the contact hole 54. The trench contact portion 60 is provided between two trench portions that are in direct contact with each other among a plurality of trench portions. The trench contact portion 60 may contain the same material as that of the emitter electrode 52. Details of the trench contact portion 60 are described below.

The contact hole 55 electrically connects the gate metal layer 50 and the gate conductive portion inside the gate trench portion 40 via the connecting portion 25. The trench contact portion 60 may be formed inside the contact hole 55.

The contact hole 56 connects the emitter electrode 52 with a dummy conductive portion inside the dummy trench portion 30. The trench contact portion 60 may be formed inside the contact hole 56.

A connecting portion 25 is connected to a front surface side metal layer such as the emitter electrode 52 or the gate metal layer 50. In an example, the connecting portion 25 is provided between the gate metal layer 50 and the gate conductive portion. The connecting portion 25 of the present example may be provided extending in the X-axis direction and electrically connected to the gate conductive portion. The connecting portion 25 may also be provided between the emitter electrode 52 and the dummy conductive portion. The connecting portion 25 is formed of a conductive material such as polysilicon doped with an impurity. The connecting portion 25 in the present example is polysilicon doped with an N type impurity (N+). The connecting portion 25 is provided above the front surface 21 of the semiconductor substrate 10 via an insulating film such as an oxide film, or the like.

The gate trench portions 40 are an example of a plurality of trench portions extending in a predetermined extending direction on the front surface 21 side of the semiconductor substrate 10. The gate trench portions 40 are arrayed at a predetermined interval in a predetermined array direction (the X-axis direction in the present example). The gate trench portion 40 is an example of the MOS gate structure provided in the semiconductor device 100. The gate trench portion 40 in the present example may include two extending parts 41 which extend in an extending direction parallel to the front surface 21 of the semiconductor substrate 10 and perpendicular to the array direction (the Y-axis direction in the present example) and two connection parts 43 which connects the two extending parts 41.

Preferably, at least a part of the connection part 43 is formed in a curved shape. Connecting end portions of the two extending parts 41 of the gate trench portion 40 can reduce electric field strength at the end portions of the extending parts 41. The gate metal layer 50 may be electrically connected to the gate conductive portion through the connecting portion 25 in the connection part 43 of the gate trench portion 40.

The dummy trench portions 30 are an example of the plurality of trench portions extending in the predetermined extending direction on the front surface 21 side of the semiconductor substrate 10. The dummy trench portion 30 is a trench portion that is electrically connected to the emitter electrode 52. The dummy trench portions 30 are arrayed with a predetermined interval along the predetermined array direction (the X-axis direction in the present example), similar to the gate trench portions 40.

The dummy trench portion 30 in the present example has two extending parts 31 extending along the extending direction (the Y-axis direction in the present example) perpendicular to an array direction that is parallel to the front surface 21 of the semiconductor substrate 10, and a connection part 33 that connects the two extending parts 31, similar to the gate trench portion 40. The dummy trench portion 30 may have an I-shape on the front surface 21 of the semiconductor substrate 10. That is, the dummy trench portion 30 may not have a connection part 33 and only have one extending part 31.

The transistor portion 70 of the present example has a structure in which one gate trench portion 40 and two dummy trench portions 30 are repeatedly arrayed. That is, the transistor portion 70 in the present example has the gate trench portions 40 and the dummy trench portions 30 at a ratio of 1:2. For example, the transistor portion 70 includes two extending parts 31 between the two extending parts 41.

It is to be noted that the ratio between the gate trench portions 40 and the dummy trench portions 30 is not limited to that in the present example. The ratio of the gate trench portions 40 may be greater than the ratio of the dummy trench portions 30, or the ratio of the dummy trench portions 30 may be greater than the ratio of the gate trench portions 40. The ratio of the gate trench portion 40 and the dummy trench portion 30 may be 1:1, or may be 2:3. The transistor portion 70 may regard all of the trench portions as the gate trench portions 40, or as structures without the dummy trench portions 30.

FIG. 1B shows an example of a cross section a-a′ in FIG. 1A. The cross section a-a′ is an XZ plane passing through the second plug region 29 in the diode portion 80. The semiconductor device 100 in the present example has the semiconductor substrate 10, the interlayer insulating film 38, the emitter electrode 52, the trench contact portion 60 and the collector electrode 24 on the cross section a-a′. The collector electrode 24 is an example of a rear surface side metal layer provided in contact with the rear surface 23 of the semiconductor substrate 10. The emitter electrode 52 and the trench contact portion 60 are one example of the front surface side electrode 53 provided above the semiconductor substrate 10. The front surface side electrode 53 may include a metal layer such as a barrier metal layer or the like.

The drift region 18 is a region of the first conductivity type which is provided in the semiconductor substrate 10. The drift region 18 is of N-type, as an example. The drift region 18 may be a region which has remained without other doping regions formed in the semiconductor substrate 10. That is, a doping concentration in the drift region 18 may be a doping concentration in the semiconductor substrate 10.

A buffer region 20 is a region of the first conductivity type which is provided in a rear surface 23 side of the semiconductor substrate 10 relative to the drift region 18. The doping concentration of the buffer region 20 is higher than the doping concentration of the drift region 18. The buffer region 20 is of N type, as an example. The buffer region 20 may function as a field stop layer which prevents a depletion layer extending from a lower surface side of the base region 14 from reaching the collector region 22 of the second conductivity type. It is to be noted that the buffer region 20 may be omitted.

The collector region 22 is provided below the buffer region 20 in the transistor portion 70. The collector region 22 has the second conductivity type. The collector region 22 is, for example, of the P+ type.

The cathode region 82 is a region of the first conductivity type with a higher doping concentration than the drift region 18, provided on the rear surface 23 of the semiconductor substrate 10 in the diode portion 80. The cathode region 82 is of N+ type, by way of example.

The collector electrode 24 is formed at the rear surface 23 of the semiconductor substrate 10. The collector electrode 24 is formed of a conductive material such as metal. The material of the collector electrode 24 may be the same as or different from the material of the emitter electrode 52.

The accumulation region 16 is a region of the first conductivity type which has a higher doping concentration than the drift region 18, provided above the drift region 18. The accumulation regions 16 are of the N type, as an example. It is noted however that the accumulation region 16 may not be provided.

The accumulation region 16 is provided in contact with the gate trench portion 40. The accumulation region 16 may or may not be in contact with the dummy trench portion 30. The accumulation region 16 may be provided in a plurality of stages in the depth direction of the semiconductor substrate 10. The accumulation region 16 in the present example is provided in two stages. Providing the accumulation region 16 can enhance the carrier injection enhancement effect (IE effect) to reduce an ON voltage of the transistor portion 70.

One or more gate trench portions 40 and one or more dummy trench portions 30 are provided at the front surface 21. Each trench portion is provided from the front surface 21 to the drift region 18. In a region provided with at least any of the emitter region 12, the base region 14, the contact region 15, the accumulation region 16, or the anode region 84, each trench portion also passes through these regions to reach the drift region 18. The configuration of the trench portion passing through the doping region is not limited to the one manufactured in the order of forming the doping region and then forming the trench portion. The configuration of the trench portion passing through the doping region includes a configuration of the doping region being formed between the trench portions after forming the trench portion.

The gate trench portion 40 has a gate trench, a gate insulating film 42, and a gate conductive portion 44 which are formed at the front surface 21. The gate insulating film 42 is formed to cover an inner wall of the gate trench. The gate insulating film 42 may be formed by oxidizing or nitriding a semiconductor on the inner wall of the gate trench. The gate conductive portion 44 is formed farther inward than the gate insulating film 42 inside the gate trench. The gate insulating film 42 insulates the gate conductive portion 44 from the semiconductor substrate 10. The gate conductive portion 44 is formed of a conductive material such as polysilicon. The gate trench portion 40 is covered with the interlayer insulating film 38 on the front surface 21.

The gate conductive portion 44 includes a region opposing the adjacent base region 14 on the side of the mesa portion 71 by sandwiching the gate insulating film 42 in a depth direction of the semiconductor substrate 10. When a predetermined voltage is applied to the gate conductive portion 44, a channel is formed by an electron inversion layer in a surface layer of the base region 14 at a boundary in contact with the gate trench.

The dummy trench portion 30 may have the same structure as the gate trench portion 40. The dummy trench portion 30 has a dummy trench, a dummy insulating film 32, and a dummy conductive portion 34 which are formed on the front surface 21 side. The dummy insulating film 32 is formed covering the inner walls of the dummy trench. The dummy conductive portion 34 is formed inside the dummy trench, and is formed farther inward than the dummy insulating film 32. The dummy insulating film 32 insulates the dummy conductive portion 34 from the semiconductor substrate 10. The dummy trench portion 30 may be covered with the interlayer insulating film 38 on the front surface 21.

The interlayer insulating film 38 is provided above the semiconductor substrate 10. The interlayer insulating film 38 of the present example is provided in contact with the front surface 21. The emitter electrode 52 is provided above the interlayer insulating film 38. In the interlayer insulating film 38, one or more of the contact holes 54 for electrically connecting the front surface side electrode 53 and the semiconductor substrate 10 are provided.

A lower end D1 of the trench contact portion 60 is shallower than a lower end D12 of the emitter region 12 in the depth direction of the semiconductor substrate 10. That is, the trench contact portion 60 does not penetrate the emitter region 12 and terminates inside the emitter region 12. The distance from the front surface 21 of the semiconductor substrate 10 to the lower end D1 of the trench contact portion 60 may be 0.3 μm or more, or 0.5 μm or less. This reduces the effect to a threshold of the semiconductor device 100 and facilitates the miniaturization of the semiconductor device 100.

The first plug region 19 is provided to cover the bottom portion of the trench contact portion 60. This can facilitate the extraction of holes from the first plug region 19 to the trench contact portion 60, and suppress latch-up of the semiconductor device 100.

The lower end of the first plug region 19 has the same depth as the lower end D12 of the emitter region 12, or is shallower than the lower end D12 of the emitter region 12 in the depth direction of the semiconductor substrate 10. That is, the first plug region 19 does not have a protruding portion that protrudes to the base region 14. In the present example, the lower end of the first plug region 19 is provided to have the same depth as the lower end D12 of the emitter region 12. In this manner, by making the lower end of the first plug region 19 have the same depth as the lower end D12 of the emitter region 12 or be shallower than the lower end D12 of the emitter region 12, the doping concentration of the base region 14 becomes uniform, the effect to the threshold of the semiconductor device 100 is reduced, and the miniaturization of the semiconductor device 100 becomes easier.

The second plug region 29 contacts the front surface side electrode 53 in a position shallower than the first plug region 19 in the depth direction of the semiconductor substrate 10. In the present example, the first plug region 19 contacts the front surface side electrode 53 on a sidewall of the trench contact portion 60 that is below the front surface 21 of the semiconductor substrate 10, and the second plug region contacts the front surface side electrode 53 on the front surface 21 of the semiconductor substrate 10. This allows a connection between the front surface side electrode 53 and the semiconductor substrate 10 near the front surface 21 with the high doping concentration in the diode portion 80, thus being able to reduce the forward voltage Vf of the diode portion 80 while suppressing the increase of the reverse recovery loss Err of the semiconductor device 100.

In the present example, the trench contact portion 60 is provided in the main region 75, and the trench contact portion 60 is not provided in the diode portion 80, the first boundary portion 190 or the second boundary portion 290. This allows the hole implantation amount from the anode region 84 to be increased, and the forward voltage Vf of the diode portion 80 to be reduced.

FIG. 1C shows an example of a cross section b-b′ in FIG. 1A. The cross section b-b′ is the XZ plane that does not pass through the second plug region 29 in the diode portion 80. The difference from FIG. 1B will be described by using FIG. 1C.

In the cross section shown in FIG. 1C, the second plug region 29 is not provided in the diode portion 80 or the second boundary portion 290. In this manner, with a region without the second plug region 29, the increase of the reverse recovery loss Err can be suppressed.

In the cross section shown in FIG. 1C, the contact region 15 is formed at the same depth as the emitter region 12. The contact region 15 may be formed to a position deeper than the emitter region 12. This can facilitate the extraction of holes from the base region 14, and suppress the latch-up of the semiconductor device 100.

FIG. 1D shows one example of a cross section c-c′ in FIG. 1A. The cross section c-c′ is the YZ cross section passing through the contact hole 54 in the transistor portion 70. The semiconductor device 100 in the present example has the semiconductor substrate 10, the interlayer insulating film 38, the emitter electrode 52, the trench contact portion 60 and the collector electrode 24 on the cross section c-c′.

The first plug region 19 in the present example is provided to cover the entire bottom portion of the trench contact portion 60 in the transistor portion 70. This can facilitate the extraction of holes from the first plug region 19 to the trench contact portion 60, and suppress latch-up of the semiconductor device 100. However, there may be a part where the bottom portion of the trench contact portion 60 is not covered by the first plug region 19.

FIG. 1E shows one example of a cross section d-d′ in FIG. 1A. The cross section d-d′ is the YZ cross section passing through the contact hole 54 in the diode portion 80. The difference from FIG. 1D will be described by using FIG. 1E.

The trench contact portion 60 is not provided in the diode portion 80. The second plug region 29 is provided on the front surface 21 of the semiconductor substrate 10 in the diode portion 80. In this manner, because the doping concentration becomes higher in the front surface 21 where the emitter electrode 52 and the semiconductor substrate 10 are electrically connected and the hole implantation amount is increased, the forward voltage Vf of the diode portion 80 can be reduced.

The second plug region 29 is provided alternately with the anode region 84 in the extending direction of the contact hole 54. That is, the second plug region 29 is provided selectively in the extending direction of the contact hole 54 (the Y-axis direction in the present example). In this manner, the forward voltage Vf of the diode portion 80 can be reduced, while the increase of the reverse recovery loss Err can be suppressed.

The cathode region 82 in the present example has a first cathode portion 181 and a second cathode portion 182. The first cathode portion 181 is a region of the first conductivity type having a doping concentration higher than that of the drift region 18. The doping concentration of the first cathode portion 181 may be higher than the doping concentration of the buffer region 20. In an example, the first cathode portion 181 is of the N+ type.

The second cathode portion 182 is a region of the second conductivity type provided to be adjacent to the first cathode portion 181 on the rear surface 23 of the semiconductor substrate 10. That is, the second cathode portion 182 may be in direct contact with the first cathode portion 181. In an example, the second cathode portion 182 is of the P+ type. The doping concentration of the second cathode portion 182 may be the same as, or may be different from the doping concentration of the collector region 22.

The first cathode portion 181 may be formed by further implanting dopants of the N type after the ion implantation of dopants of the P type by the ion implantation process for forming the second cathode portion 182. Conversely, the second cathode portion 182 may be formed by further implanting the dopants of the P type after the ion implantation of the dopants of the N type by the ion implantation process for forming the first cathode portion 181.

The first cathode portion 181 and the second cathode portion 182 are arranged repeatedly alternately in a predetermined direction. The first cathode portion 181 and the second cathode portion 182 may be arrayed alternately in the trench array direction (the X-axis direction in the present example), or may be alternately arrayed in the trench extending direction (the Y-axis direction in the present example). In the present example, the first cathode portion 181 and the second cathode portion 182 are arranged alternately in the trench extending direction. The first cathode portion 181 and the second cathode portion 182 may be arranged in stripe shapes in a top view. This allows the trade-off between the forward voltage Vf of the diode portion 80 and the reverse recovery loss Err of the semiconductor device 100 to be adjusted.

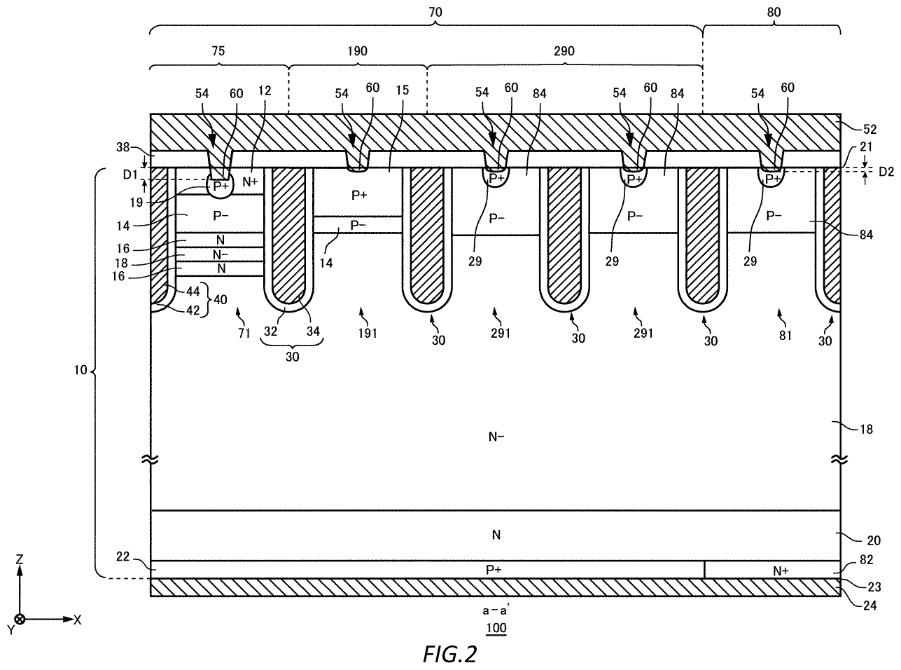

FIG. 2 shows a variant example of the cross section a-a′ of the semiconductor device 100. In the variant example of FIG. 2, the trench contact portion 60 is provided in the diode portion 80, the first boundary portion 190 and the second boundary portion 290, which is different from the example of FIG. 1B. The difference from FIG. 1B will be described by using FIG. 2.

In the example shown in FIG. 2, the lower end of the first plug region 19 is deeper than the lower end of the emitter region 12 in the depth direction of the semiconductor substrate 10. That is, the first plug region 19 is provided to protrude to the base region 14. This can facilitate the extraction of holes from the base region 14, and suppress the latch-up of the semiconductor device 100.

A lower end D2 of the trench contact portion 60 provided in the diode portion 80 is shallower than the lower end D1 of the trench contact portion 60 provided in the transistor portion 70. In an example, the distance from the front surface 21 of the semiconductor substrate 10 to the lower end D2 of the trench contact portion 60 in the diode portion 80 is from 0 μm to 0.1 μm. This allows a connection between the front surface side electrode 53 and the semiconductor substrate 10 near the front surface 21 with the higher doping concentration in the diode portion 80, thus being able to reduce the forward voltage Vf of the diode portion 80 while suppressing the increase of the reverse recovery loss Err of the semiconductor device 100.

The trench contact portion 60 in the diode portion 80 may be formed by filling a region where the front surface 21 of the semiconductor substrate 10 is slightly etched by the operations used to form the contact hole 54 in the diode portion 80 with a conductive material. That is, the trench contact portion 60 may be formed in the diode portion 80 without requiring a separate step.

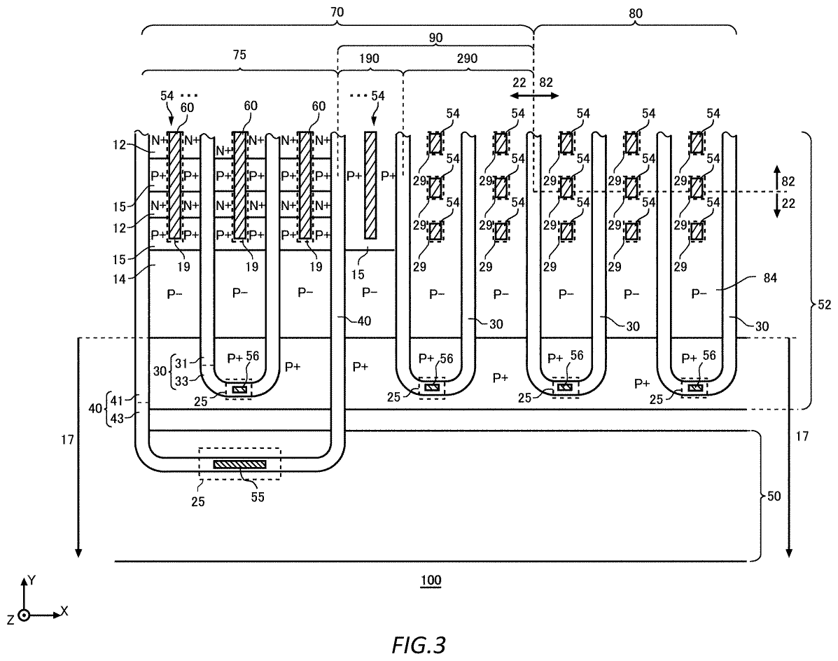

FIG. 3 shows a variant example of the upper surface of the semiconductor device 100. The difference from FIG. 1A is described using FIG. 3.

The second plug region 29 may be provided along the shape of the contact hole 54 in a top view. In the present specification, the second plug region 29 being provided along the shape of the contact hole 54 means that dopants are implanted into the region of the semiconductor substrate 10 exposed through the aperture of contact holes 54 during implanting ions to form the second plug region 29. Accordingly, even if the region where the contact holes 54 are provided and the region where the second plug region 29 is provided do not completely coincide in the top view due to the diffusion of dopants by a thermal annealing step, etc. after implanting ions, the second plug region 29 may be included in the examples where the second plug region 29 is provided along the shape of the contact hole 54.

In the variant example of FIG. 3, one contact hole 54 is provided to extend in the trench extending direction in the main region 75, and a plurality of the contact holes 54 are provided selectively in the trench extending direction in the second boundary portion 290 and the diode portion 80. That is, in the trench extending direction, the length of the contact hole 54 in the second boundary portion 290 and the diode portion 80 is shorter than the length of the contact hole 54 in the main region 75.

By providing the second plug region 29 along the shape of the contact hole 54, when the second plug region 29 is selectively formed, an additional resist mask or the like can be eliminated. This reduces the number of steps used in manufacturing the semiconductor device 100, thereby reducing the manufacturing cost of the semiconductor device 100.

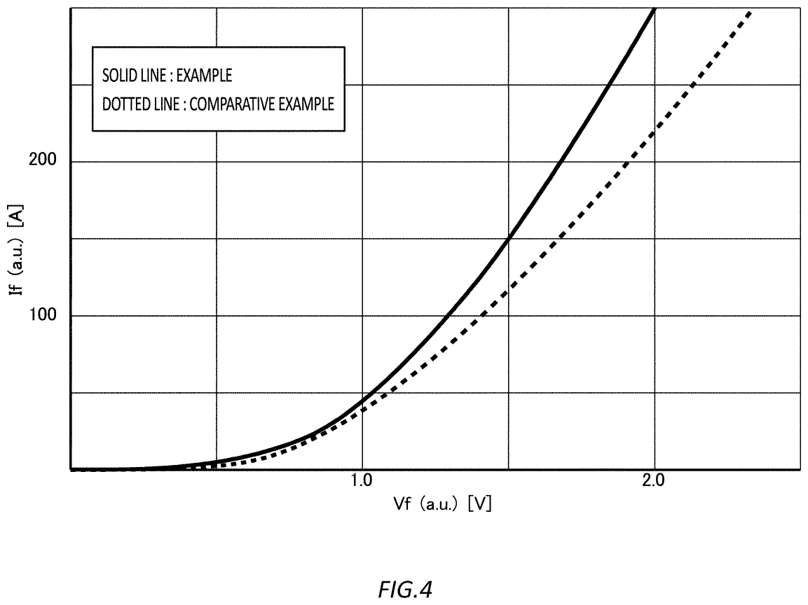

FIG. 4 shows a Vf-If characteristics of the semiconductor device 100 in the present example and the semiconductor device in a comparative example. The Vf-If characteristic of the present example is shown by a solid line, and the Vf-If characteristic of the comparative example is shown by a dotted line. The horizontal axis shows the forward voltage Vf, the vertical axis shows the forward current If, and numerical values of the vertical axis and the horizontal axis are normalized.

In the present specification, the semiconductor device in the comparative example means a semiconductor device where the second plug region contacts the front surface side electrode in a position in the same depth as the first plug region or deeper than the first plug region in the depth direction of the semiconductor substrate. FIG. 4 shows the Vf-If characteristic about the comparative example where the first plug region and the second plug region are in contact with the front surface side electrode at the same depth. The semiconductor device 100 in the present example is different from the semiconductor device in the comparative example in that the second plug region 29 contacts the front surface side electrode 53 in a position shallower than the first plug region 19.

In the semiconductor device 100 in the present example, the numerical value of the forward voltage Vf for flowing the same forward current If is smaller than the semiconductor device in the comparative example. That is, the semiconductor device 100 of the present example has the forward voltage Vf reduced when compared to the semiconductor device in the comparative example. In the semiconductor device 100 in the present example, by having the second plug region 29 contacting the front surface side electrode 53 in the position shallower than the first plug region 19, the front surface side electrode 53 and the semiconductor substrate 10 are electrically connected near the front surface 21 with a higher doping concentration than the comparative example, the hole implantation from the anode region 84 can be improved, and the forward voltage Vf can be reduced.

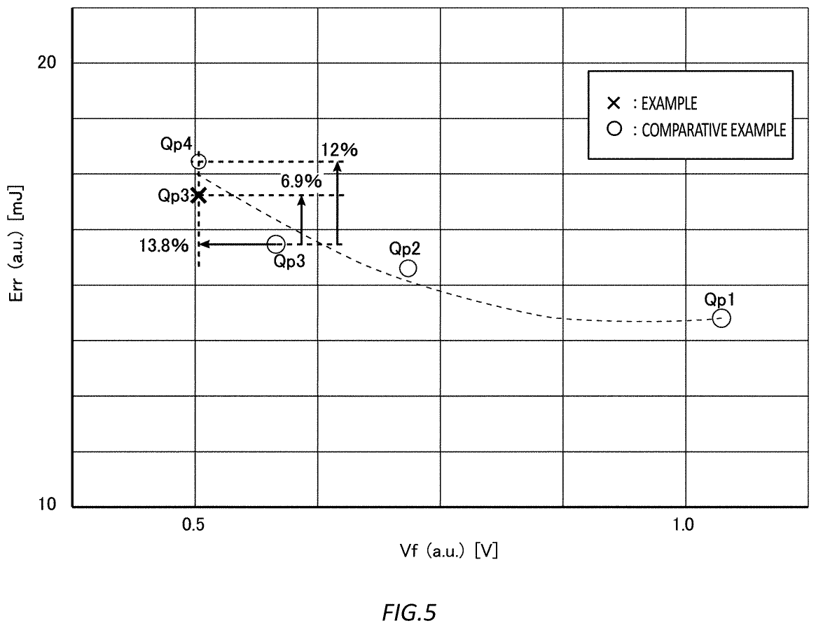

FIG. 5 shows a Vf-Err characteristics of the semiconductor device 100 in the present example and the semiconductor device in the comparative example. The Vf-Err characteristic of the present example is shown by a solid line, and the Vf-Err characteristic of the comparative example is shown by a dotted line. The horizontal axis shows the forward voltage Vf, the vertical axis shows the reverse recovery loss Err, and numerical values of the vertical axis and the horizontal axis are normalized.

For the semiconductor device in the comparative example, four data points with different doping concentrations in the anode region are shown by white circles. Qp1, Qp2, Qp3, and Qp4 show the doping concentrations of the anode region, with Qp1 showing the lowest doping concentration, followed by Qp2 and Qp3, which showing higher doping concentrations, and Qp4 showing the highest doping concentration. It can be known from FIG. 5 that in the semiconductor device in the comparative example, as the doping concentration of the anode region is increased, the forward voltage Vf decreases and the reverse recovery loss Err tends to increase.

FIG. 5 shows the Vf-Err characteristic of the semiconductor device 100 in the present example when the doping concentration of the anode region 84 is Qp3, marked with a cross symbol. In the semiconductor device in the comparative example, when the doping concentration of the anode region is increased from Qp3 to Qp4, the forward voltage Vf decreases by 13.8%. On the other hand, in the semiconductor device 100 in the present example, even if the doping concentration of the anode region 84 is Qp3, the forward voltage Vf decreases by 13.8%. Therefore, the semiconductor device 100 in the present example can reduce the forward voltage Vf without increasing the doping concentration of the anode region 84.

In the semiconductor device in the comparative example, when the doping concentration in the anode region is increased from Qp3 to Qp4, the reverse recovery loss Err increases by 12%. On the other hand, in the semiconductor device 100 in the present example, the increased amount in reverse recovery loss Err remains to be 6.9%. That is, compared to the case where the doping concentration is increased from Qp3 to Qp4, the increased amount in reverse recovery loss Err can be reduced by 5.1%. Therefore, the semiconductor device 100 in the present example can improve the Vf-Err characteristic compared to the case where the doping concentration in the anode region 84 is increased.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that the embodiments to which such alterations or improvements are made can be included in the technical scope of the present invention.

It should be noted that the operations, procedures, steps, stages, and the like of each process performed by an apparatus, system, program, and method shown in the claims, the specification, or the drawings can be realized in any order as long as the order is not indicated by “prior to,” “before,” or the like and as long as the output from a previous process is not used in a later process. Even if the operation flow is explained using phrases such as “first” or “next” in the claims, specification, or drawings, it does not necessarily mean that the process must be performed in this order.

### EXPLANATION OF REFERENCES

10: semiconductor substrate; 12: emitter region; 14: base region; 15: contact region; 16: accumulation region; 17: well region; 18: drift region; 19: first plug region; 20: buffer region; 21: front surface; 22: collector region; 23: rear surface; 24: collector electrode; 25: connecting portion; 29: second plug region; 30: dummy trench portion; 31: extending part; 32: dummy insulating film; 33: connection part; 34: dummy conductive portion; 38: interlayer insulating film; 40: gate trench portion; 41: extending part; 42: gate insulating film; 43: connection part; 44: gate conductive portion; 50: gate metal layer; 52: emitter electrode; 53: front surface side electrode; 54: contact hole; 55: contact hole; 56: contact hole; 60: trench contact portion; 70: transistor portion; 71: mesa portion; 75: main region; 80: diode portion; 81: mesa portion; 82: cathode region; 84: anode region; 90: boundary region; 100: semiconductor device; 181: first cathode portion; 182: second cathode portion; 190: first boundary portion; 191: mesa portion; 290: second boundary portion; 291: mesa portion.

What is claimed is:

1. A semiconductor device with a transistor portion and a diode portion, comprising:
a plurality of trench portions provided on a front surface of a semiconductor substrate;
a drift region of a first conductivity type provided in the semiconductor substrate; and
a front surface side electrode provided above the semiconductor substrate,
wherein the transistor portion has:
a base region of a second conductivity type provided above the drift region;
an emitter region of a first conductivity type with a higher doping concentration than the drift region, provided above the base region;
a contact region of a second conductivity type with a higher doping concentration than the base region, provided above the base region;
a trench contact portion provided on a front surface of the semiconductor substrate; and
a first plug region of a second conductivity type with a higher doping concentration than the base region, under the trench contact portion,
wherein the diode portion has:
an anode region of a second conductivity type provided above the drift region; and
a second plug region of a second conductivity type with a higher doping concentration than the anode region,
wherein the second plug region contacts the front surface side electrode in a position shallower than the first plug region in a depth direction of the semiconductor substrate.

2. The semiconductor device according to claim 1, wherein the second plug region contacts the front surface side electrode in a front surface of the semiconductor substrate.

3. The semiconductor device according to claim 1, wherein a lower end of the trench contact portion provided in the diode portion is shallower than a lower end of the trench contact portion provided in the transistor portion.

4. The semiconductor device according to claim 1, wherein in the diode portion, the second plug region is provided alternately with the anode region in a trench extending direction of the plurality of trench portions.

5. The semiconductor device according to claim 4, wherein in the trench extending direction, a width of the first plug region provided in the transistor portion is greater than a width of the second plug region provided in the diode portion.

6. The semiconductor device according to claim 1, wherein a lower end of the first plug region is deeper than a lower end of the emitter region in the depth direction of the semiconductor substrate.

7. The semiconductor device according to claim 1, wherein a lower end of the first plug region has a depth identical to a lower end of the emitter region, or is shallower than a lower end of the emitter region in the depth direction of the semiconductor substrate.

8. The semiconductor device according to claim 1, wherein a doping concentration of the anode region is lower than a doping concentration of the base region.

9. The semiconductor device according to claim 1, wherein the doping concentration of the anode region is from 1E16 cm⁻³ to 1E18 cm⁻³.

10. The semiconductor device according to claim 1, wherein a lower end of the trench contact portion is shallower than a lower end of the emitter region in the depth direction of the semiconductor substrate.

11. The semiconductor device according to claim 1, wherein:
the transistor portion has:
a main region with the emitter region; and
a boundary region provided closer than the main region to the diode portion,
the boundary region has:
a first boundary portion including the contact region on the front surface of the semiconductor substrate; and
a second boundary portion including the anode region, which is provided closer than the first boundary portion to the diode portion.

12. The semiconductor device according to claim 11, wherein the trench contact portion is not provided in the boundary region.

13. The semiconductor device according to claim 11, wherein a width of the contact region provided in the first boundary portion in a trench extending direction is greater than a width in a trench extending direction of the contact region provided in the main region.

14. The semiconductor device according to claim 11, wherein the second boundary portion includes the second plug region.

15. The semiconductor device according to claim 14, wherein in a trench extending direction of the plurality of trench portions, a width of the second plug region provided in the second boundary portion is smaller than a width of the first plug region.

16. The semiconductor device according to claim 1, wherein:
the diode portion has a cathode region of a first conductivity type with a higher doping concentration than the drift region on a rear surface of the semiconductor substrate; and
the cathode region includes a first cathode portion of a first conductivity type and a second cathode portion of a second conductivity type.

17. The semiconductor device according to claim 16, wherein the first cathode portion and the second cathode portion are repeatedly arranged alternately in a predetermined direction.

18. The semiconductor device according to claim 1, comprising an accumulation region of a first conductivity type with a higher doping concentration than the drift region, which is provided above the drift region in the transistor portion.

19. The semiconductor device according to claim 1, comprising
an interlayer insulating film with a contact hole provided thereon for electrically connecting the front surface side electrode to the semiconductor substrate above the semiconductor substrate,
wherein the second plug region is provided along a shape of the contact hole in a top view.

20. The semiconductor device according to claim 2, comprising
an interlayer insulating film with a contact hole provided thereon for electrically connecting the front surface side electrode to the semiconductor substrate above the semiconductor substrate,
wherein the second plug region is provided along a shape of the contact hole in a top view.
